(19) United States
(12) Patent Application Publication
(10) Pub. No.: US 2016/0079415 A1
(43) Pub. Date: Mar. 17, 2016

(54) SEMICONDUCTOR DEVICE AND MANUFACTURING METHOD THEREOF

(71) Applicant: KABUSHIKI KAISHA TOSHIBA, Tokyo (JP)

(72) Inventors: Emiko SUGIZAKI, Ota Tokyo (JP); Yoshiyuki KONDO, Yokohama Kanagawa (JP)

(73) Assignee: KABUSHIKI KAISHA TOSHIBA, Tokyo (JP)

(21) Appl. No.: 14/588,162

(22) Filed: Dec. 31, 2014

(30) Foreign Application Priority Data
Sep. 11, 2014 (JP) 2014-185354

(51) Int. Cl. H01L 29/78; H01L 29/66

(52) U.S. Cl. CPC H01L 29/7816; H01L 29/66681

(57) ABSTRACT

A device includes a gate and a gate dielectric film on a substrate. A first diffusion-layer of a first conductivity-type is in a surface of the substrate. A second diffusion-layer of a second conductivity-type is under the first diffusion-layer and forms a PN-junction with the bottom of the first diffusion-layer. A drain-layer of the first conductivity-type is in the substrate on one side of the gate. A source-layer of the second conductivity-type is provided in the substrate on other side of the gate. A first sidewall is on a side surface of the gate and on a top surface of the first diffusion-layer. A conductive-layer is on the source-layer at a position separated from the first sidewall. A top surface of the substrate in a separation region between the first sidewall and the conductive-layer is at a position equal to or lower than a bottom of the first diffusion-layer.

### CROSS REFERENCE TO RELATED APPLICATIONS

This application is based upon and claims the benefit of priority from the prior Japanese Patent Application No. 2014-185354, filed on Sep. 11, 2014, the entire contents of which are incorporated herein by reference.

### FIELD

The embodiments of the present invention relate to a semiconductor device and manufacturing method thereof.

### BACKGROUND

A tunnel field effect transistor (TFET) has been developed, in order to decrease switching energy in digital circuit than that of the circuit composed of conventional MOSFET. The TFET is a transistor that controls an ON/OFF state of elements using a tunnel current observed at a PN junction in semiconductors or at a Schottky barrier junction between metal and a semiconductor.

To obtain a large ON-state current and a steep subthreshold characteristic in the TFET, a TFET including a vertical PN junction has been proposed. The vertical PN junction is a PN junction in which a P-type semiconductor and an N-type semiconductor are adjacent in a direction vertical (perpendicular) to the bottom surface of a gate electrode. For example, in an N-channel vertical PNiN-TFET, a P-type extension layer and an N-type pocket layer constituting a vertical PN junction are provided near a P-type source layer.

However, when the vertical PNiN-TFET is to be formed, N-type impurities of the pocket layer are formed by counter-doping. Thus an N-type impurity diffusion layer is formed also in a surface of the source-layer formation region. Therefore, when the P-type source layer is to be formed, P-type impurities of a higher concentration than an N-type impurity concentration of the pocket layer need to be introduced into the source-layer formation region. That is, to cause the source layer to have the opposite conductivity type to that of the pocket layer, impurities of the opposite conductivity type to that of the impurities of the pocket layer are counter-doped to the source-layer formation region. However, there is a case where the counter-doped P-type impurities are diffused and the source layer functions substantially as an N-type diffusion layer. Or, there is a case where the P-type impurities cannot be sufficiently activated and a diffusion layer region of the pocket layer remains in the source layer. If the N-type diffusion layer region remains in the P-type source layer, a voltage of the source layer is directly applied to the pocket layer. As a result, the transistor does not operate as a TFET, but performs a switching operation such as a MOSFET (Metal-Oxide-Semiconductor FET). Therefore, the subthreshold characteristic of the transistor is degraded, and a leak current is increased.

### BRIEF DESCRIPTION OF THE DRAWINGS

FIG. 1 is a cross-sectional view showing an example of a configuration of an N-type tunnel field effect transistor according to a first embodiment;

FIGS. 2A to 6B are cross-sectional views showing an example of the manufacturing method of the N-TFET according to the first embodiment;

FIG. 7 is a cross-sectional view showing an example of a configuration of a TFET according to a second embodiment;

FIGS. 8A to 11B are cross-sectional views showing an example of a manufacturing method of the N-TFET according to the second embodiment;

FIG. 12 is a cross-sectional view showing an example of a configuration of a TFET according to a third embodiment;

FIGS. 13A to 14B are cross-sectional views showing an example of a manufacturing method of the N-TFET according to the third embodiment; and

FIG. 15 is a cross-sectional view showing a configuration of a TFET according to a modification of the embodiments.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a semiconductor substrate on which semiconductor elements are provided is assumed as “an upper direction”. Therefore, the term “upper direction” or “lower direction” occasionally differs from an upper direction or a lower direction based on a gravitational acceleration direction.

A semiconductor device according to an embodiment includes a semiconductor substrate. A gate dielectric film is provided on the semiconductor substrate. A gate electrode is provided on the gate dielectric film. A first diffusion layer of a first conductivity type is provided in a part of a surface of the semiconductor substrate under the gate dielectric film. A second diffusion layer of a second conductivity type is provided in the semiconductor substrate under the first diffusion layer. The second conductivity type is a conductivity type different from the first conductivity type. The second diffusion layer is in contact with a bottom portion of the first diffusion layer and forms a PN junction with the bottom portion of the first diffusion layer. A drain layer of the first conductivity type is provided in the semiconductor substrate on one side of the gate electrode. A source layer of the second conductivity type is provided in the semiconductor substrate on other side of the gate electrode to be adjacent to the second diffusion layer. A first sidewall dielectric film is provided on a side surface of the gate electrode and on a top surface of the first diffusion layer. A conductive layer is provided on the source layer at a position separated from the first sidewall dielectric film. A top surface of the semiconductor substrate in a separation region between the first sidewall dielectric film and the conductive layer is at a position equal to or lower than a bottom surface of the first diffusion layer.

### First Embodiment

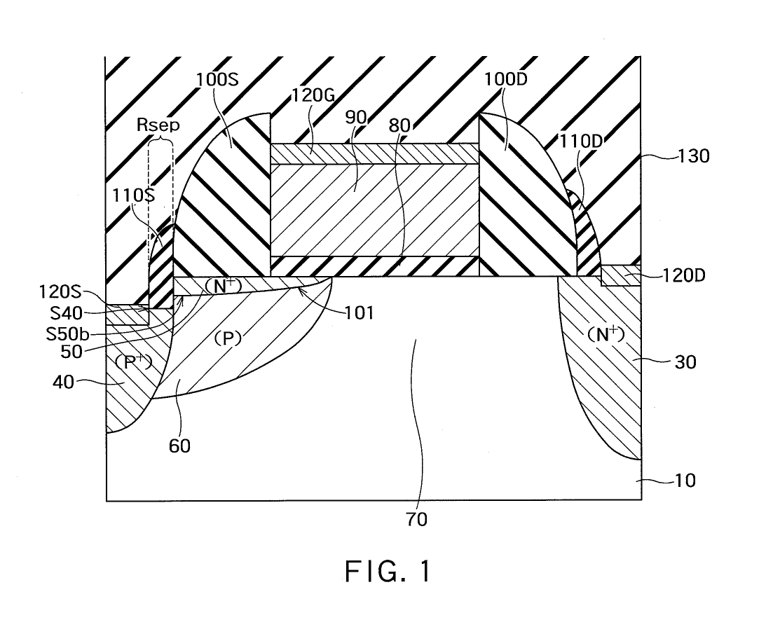

FIG. 1 is a cross-sectional view showing an example of a configuration of an N-type tunnel field effect transistor (hereinafter, also TFET) according to a first embodiment. The TFET according to the first embodiment includes a semiconductor substrate 10, a drain layer 30, a source layer 40, a pocket layer 50 being a first diffusion layer, an extension layer 60 being a second diffusion layer, a low-concentration layer 70, a gate dielectric film 80, a gate electrode 90, first sidewall dielectric films 100S and 100D, second sidewall dielectric films 110S and 110D, a source silicide layer 120S being a conductive layer, a drain silicide layer 120D, a gate silicide layer 120G, and an interlayer dielectric film 130.

The TFET according to the first embodiment is formed on, for example, a bulk silicon substrate. Alternatively, the TFET according to the first embodiment can be formed on a SOI (Silicon On Insulator) substrate, a SON (Silicon On Nothing) substrate, a GeOI (Germanium On Insulator) substrate, a SiGe-OI (SiGe On Insulator) substrate, or a III-V compound semiconductor substrate. FIG. 1 shows an N-TFET formed on a bulk silicon substrate.

The gate dielectric film 80 is provided on the semiconductor substrate 10. The gate dielectric film 80 is made of, for example, a silicon dioxide film or a dielectric film having a higher dielectric constant than that of the silicon dioxide film.

The gate electrode 90 is provided on the gate dielectric film 80. The gate electrode 90 is made of a conductive material such as doped polysilicon or metal.

The gate silicide layer 120G is provided on the gate electrode 90. The gate silicide layer 120G is made of metal silicide such as nickel silicide.

The first sidewall dielectric films 100S and 100D are provided to cover opposite side surfaces of the gate dielectric film 80, the gate electrode 90, and the gate silicide layer 120G, respectively. The first sidewall dielectric film 100S on a source side covers the side surfaces of the gate dielectric film 80, the gate electrode 90, and the gate silicide layer 120G on the source side and covers a part of a top surface of the pocket layer 50. The first sidewall dielectric film 100S thereby separates a side surface of the pocket layer 50 on the source side from the gate dielectric film 80 and the gate electrode 90. The first sidewall dielectric film 100D on a drain side covers the side surfaces of the gate dielectric film 80, the gate electrode 90, and the gate silicide layer 120G on a side of the drain layer 30. The first sidewall dielectric films 100S and 100D are formed of an insulating film such as a TEOS (Tetraethyl Orthosilicate) film.

The second sidewall dielectric film 110S is provided to cover a part of a side surface of the first sidewall dielectric film 100S, the side surface of the pocket layer 50, and an upper portion of a side surface of the extension layer 60 on the source side. The second sidewall dielectric film 110S is provided on the semiconductor substrate 10 in a separation region Rsep between the first sidewall dielectric film 100S and the source silicide layer 120S and between the pocket layer 50 and the source silicide layer 120S. The second sidewall dielectric film 110S thereby separates the source silicide layer 120S from the first sidewall dielectric film 100S and separates the source silicide layer 120S from the pocket layer 50.

The second sidewall dielectric film 110D is provided to cover a part of a side surface of the first sidewall dielectric film 100D on the drain side. The second sidewall dielectric films 110S and 110D are made of an insulating film such as a silicon nitride film.

The pocket layer 50 contains impurities of an N type as a first conductivity type at a high concentration and is provided in a part of a surface of the semiconductor substrate 10 under the first sidewall dielectric film 100S and the gate electrode 90. The side surface of the pocket layer 50 extends in a direction substantially vertical to the surface of the semiconductor substrate 10 and is covered with the second sidewall dielectric film 110S.

The extension layer 60 contains impurities of a P type as a second conductivity type and is provided in the semiconductor substrate 10 under the pocket layer 50. A top surface of the extension layer 60 is in contact with a bottom portion of the pocket layer 50 to form a vertical-direction PN junction portion (hereinafter, also “vertical PN junction portion”) 101. That is, the pocket layer 50 and the extension layer 60 are in contact with each other in a direction vertical (substantially perpendicular) to the surface of the semiconductor substrate 10 to form the vertical PN junction portion 101. A junction face of the PN junction portion 101 orients in the vertical direction. The extension layer 60 is adjacent to the source layer 40 and is electrically connected to the source layer 40.

The drain layer 30 is a semiconductor layer containing N-type impurities (phosphorus or arsenic, for example) of a high concentration and is provided in a part of the surface of the semiconductor substrate 10 located on one side of the gate electrode 90. The drain silicide layer 120D is provided on the drain layer 30 and is made of metal silicide such as nickel silicide.

The source layer 40 is a semiconductor layer containing P-type impurities (boron, for example) of a high concentration and is provided in a part of the surface of the semiconductor substrate 10 located on the other side of the gate electrode 90. The source layer 40 is provided adjacent to the extension layer 60 and under the second sidewall dielectric film 110S and the source silicide layer 120S. In the first embodiment, the source layer 40 is provided in the semiconductor substrate 10 in the separation region Rsep.

In the separation region Rsep, the second sidewall dielectric film 110S covers the side surface of the pocket layer 50 and a top surface S40 of the source layer 40 (that is, the semiconductor substrate 10) is at a lower position than a bottom surface S50b of the pocket layer 50. This is because the semiconductor substrate 10 in a formation region of the source layer 40 is recessed to remove the N-type impurities having been introduced into the formation region of the source layer 40 at a formation step of the pocket layer 50 as will be explained later.

The source silicide layer 120S is provided on the source layer 40 and is separated from the pocket layer 50 and the first sidewall dielectric film 100S by the second sidewall dielectric film 110S. The source silicide layer 120S is made of metal silicide such as nickel silicide similarly to the drain silicide layer 120D.

The low-concentration layer 70 is provided in the surface of the semiconductor substrate 10 below the gate electrode 90 between the pocket layer 50 and the drain layer 30 and between the extension layer 60 and the drain layer 30. The low-concentration layer 70 is an intrinsic semiconductor region having an impurity concentration equal to or lower than 10¹⁸ cm⁻³. Surfaces of the pocket layer 50 and the low-concentration layer 70 below the gate electrode 90 function as a channel region.

To turn on the TFET according to the first embodiment, a positive voltage is applied to the gate electrode 90 and a positive voltage is applied to the drain layer 30. When the positive voltage is applied to the gate electrode 90, a channel is formed in the surfaces of the pocket layer 50 and the low-concentration layer 70. Therefore, the pocket layer 50 is electrically connected to the drain layer 30. Meanwhile, the voltage applied to the gate electrode 90 applies an electric field to the vertical PN junction portion 101 between the pocket layer 50 and the extension layer 60. A tunnel current thereby flows in the vertical PN junction portion 101 in a direction perpendicular to the surface of the semiconductor substrate 10. As a result, the current flows between the drain layer 30 and the source layer 40 through the low-concentration layer 70, the pocket layer 50, and the extension layer 60. The TFET according to the first embodiment is brought to an ON state in this way.

In the TFET according to the first embodiment, the top surface S40 of the source layer 40 (the semiconductor substrate 10) in the separation region Rsep is at a position lower than the bottom surface S50b of the pocket layer 50. This is because the top surface S40 of the semiconductor substrate 10 is etched deeper than the bottom surface S50b of the pocket layer 50 to remove the semiconductor substrate 10 in the source-layer formation region into which the N-type impurities have been introduced at the formation step of the pocket layer 50. This etching step removes the N-type impurities in the source-layer formation region and thus can suppress an N-type semiconductor layer from remaining in the source layer 40. Accordingly, a leak current between the source layer 40 and the pocket layer 50 can be suppressed.

The second sidewall dielectric film 110S is provided on the semiconductor substrate 10 in the separation region Rsep and the second sidewall dielectric film 110S covers the side surface of the pocket layer 50. Therefore, the second sidewall dielectric film 110S is interposed between the pocket layer 50 and the source silicide layer 120S and the source silicide layer 120S is separated from the pocket layer 50. A direct contact between the source silicide layer 120S and the pocket layer 50 is thereby suppressed and a leak current between the source layer 40 and the pocket layer 50 can be suppressed.

If a leak current flows between the source layer 40 and the pocket layer 50, the TFET causes a current to flow between the source layer 40 and the drain layer 30 regardless of a tunnel current in the vertical PN junction portion 101 when a channel region is inverted, similarly to the MOSFET. That is, the TFET performs a switching operation in a MOSFET mode. Therefore, the leak current between the source layer 40 and the pocket layer 50 interrupts a switching operation due to the tunnel current and becomes a cause of degradation in subthreshold characteristics.

On the other hand, the TFET according to the first embodiment can suppress a leak current between the source layer 40 and the pocket layer 50 as mentioned above. Therefore, the TFET according to the first embodiment can suppress the switching operation in the MOSFET mode and can perform the switching operation due to the tunnel current in the vertical PN junction portion 101. Degradation in the subthreshold characteristics of the TFET can be thereby suppressed.

The second sidewall dielectric film 110S covers the side surface of the pocket layer 50 and the source layer 40 is not in contact with the side surface of the pocket layer 50. Accordingly, the transistor can be controlled to be ON/OFF based on the tunnel current in the vertical PN junction portion 101.

Furthermore, the pocket layer 50 is formed not only under the gate electrode 90 but also under the first sidewall dielectric film 100S located on the side surface of the gate electrode 90 and extends from the channel region under the gate electrode 90 toward the source layer 40 up to the second sidewall dielectric film 110S. Therefore, an interface between the side surface of the pocket layer 50 and the second sidewall dielectric film 110S is separated from the channel region and is provided near an interface between the source layer 40 and the extension layer 60. When the source-layer formation region is etched, crystal defects are likely to occur in the interface between the side surface of the pocket layer 50 and the second sidewall dielectric film 110S due to etching. If there is an interface having the crystal defects near the channel region, a leak current may occur. On the other hand, because the interface between the side surface of the pocket layer 50 and the second sidewall dielectric film 110S is separated from the channel region in the first embodiment, the leak current between the source layer 40 and the pocket layer 50 can be further suppressed.

A manufacturing method of the TFET according to the first embodiment is explained next.

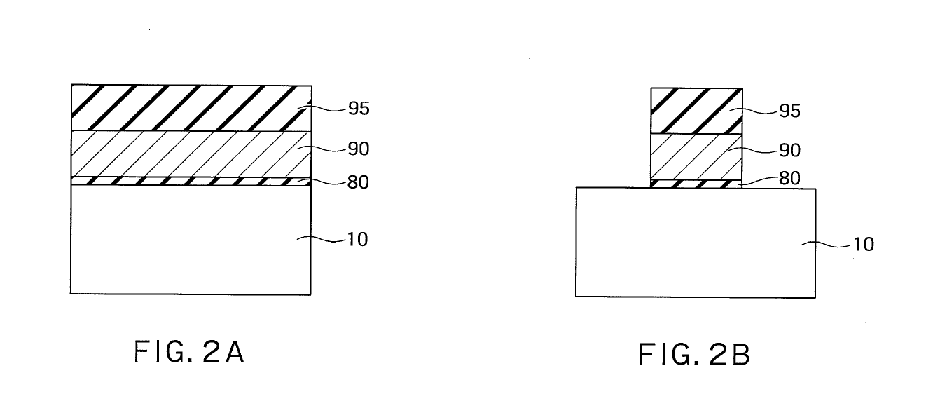

FIGS. 2A to 6B are cross-sectional views showing an example of the manufacturing method of the N-TFET according to the first embodiment.

The gate dielectric film 80 is first formed on the semiconductor substrate 10. The gate dielectric film 80 is formed of, for example, a silicon dioxide film or a high dielectric film (such as HfO₂) having a higher dielectric constant than that of the silicon dioxide film. The semiconductor substrate 10 can be any of a bulk silicon substrate, a SOI substrate, a SON substrate, a GeOI substrate, a SiGe-OI substrate, and a III-V compound semiconductor substrate.

Next, a material of the gate electrode 90 is deposited on the gate dielectric film 80 using a CVD (Chemical Vapor Deposition) method. The material of the gate electrode 90 can be formed of, for example, doped polysilicon or metal (such as TiN). When the doped polysilicon is used as the gate electrode 90, the gate electrode 90 in the N-TFET contains N-type impurities.

A material of a hard mask 95 is then deposited on the material of the gate electrode 90 using the CVD method. The hard mask 95 is formed of an insulating film such as a silicon nitride film. A structure shown in FIG. 2A is thereby obtained.

Next, the hard mask 95 is processed in a pattern of the gate electrode 90 using a lithography technique and a RIE (Reactive Ion Etch) method. The materials of the gate electrode 90 and the gate dielectric film 80 are then processed in the pattern of the gate electrode 90 by the RIE method using the hard mask 95 as a mask as shown in FIG. 2B.

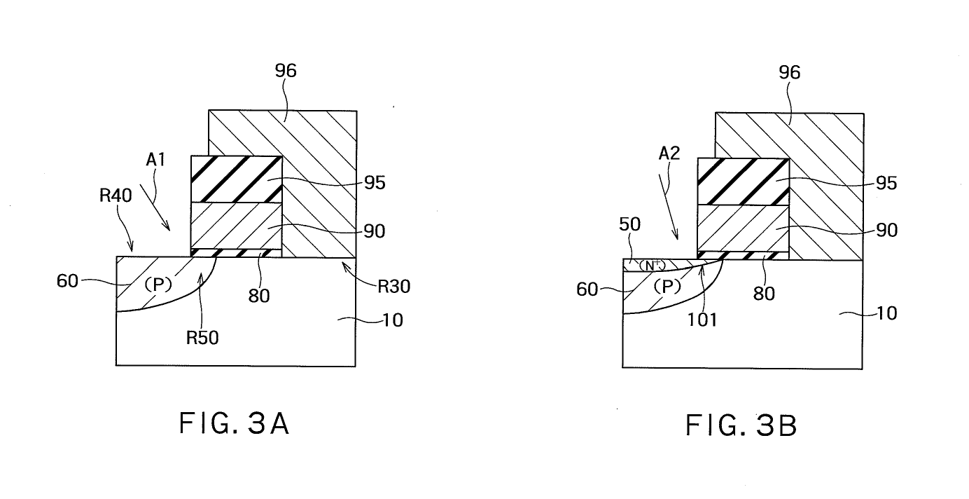

Next, a drain-layer formation region R30 is covered with a resist 96 using the lithography technique as shown in FIG. 3A. P-type impurity (such as B or BF₂) ions for forming the extension layer 60 as the second diffusion layer are subsequently implanted from a source-layer formation region R40 toward a pocket-layer formation region (first-diffusion-layer formation region) R50 adjacent to the region R40 using the resist 96 as a mask. At that time, the P-type impurity ions are implanted in an oblique direction as shown by an arrow A1 to be introduced also into the semiconductor substrate 10 below the gate electrode 90. The P-type impurities of the extension layer 60 are thereby introduced into the source-layer formation region R40 and the pocket-layer formation region R50 as shown in FIG. 3A.

N-type impurity (such as phosphorus or arsenic) ions for forming the pocket layer 50 as the first diffusion layer are further implanted from the source-layer formation region R40 toward the pocket-layer formation region R50 adjacent to the region R40 using the resist 96 as a mask. At that time, the N-type impurity ions are implanted in an oblique direction as shown by an arrow A2 in FIG. 3B to be introduced also into the semiconductor substrate 10 below the gate electrode 90. The N-type impurities of the pocket layer 50 are thereby introduced into the source-layer formation region R40 and the pocket-layer formation region R50 as shown in FIG. 3B. The order of introduction of the P-type impurities of the extension layer 60 and the N-type impurities of the pocket layer 50 can be changed.

Next, a thermal treatment such as RTA (Rapid Thermal Anneal) is performed for crystal recovery and impurity activation. The extension layer 60 and the pocket layer 50 are thereby formed. At that time, a bottom portion of the pocket layer 50 and a top portion of the extension layer 60 are in contact with each other in a direction vertical (substantially perpendicular) to the surface of the semiconductor substrate 10 and form the vertical PN junction portion 101.

The pocket layer 50 can be formed by epitaxially growing silicon containing the N-type impurities after selectively wet-etching the semiconductor substrate 10 in the pocket-layer formation region R50.

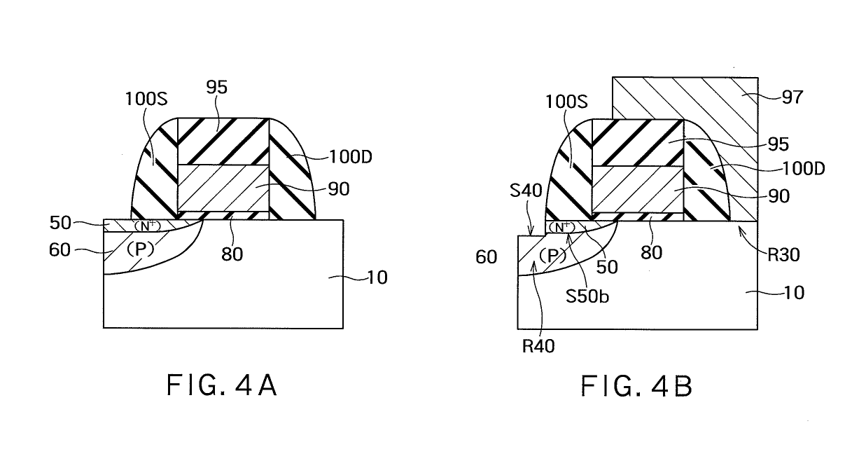

After removal of the resist 96, a material of the first sidewall dielectric films 100S and 100D is deposited on the semiconductor substrate 10. The material of the first sidewall dielectric films 100S and 100D is formed of an insulating film such as a TEOS film. Next, the material is etched back by the RIE method, thereby forming the first sidewall dielectric films 100S and 100D to cover the opposite side surfaces of the hard mask 95 and the gate electrode 90, respectively, as shown in FIG. 4A. The first sidewall dielectric film 100D covers the side surfaces of the hard mask 95 and the gate electrode 90 on the drain side. The first sidewall dielectric film 100S covers the side surfaces of the hard mask 95 and the gate electrode 90 on the source side. The first sidewall dielectric film 100S is formed also on a part of the top surface of the pocket layer 50 on the side of the gate electrode 90.

Next, the drain-layer formation region R30 is covered with a resist 97 using the lithography technique as shown in FIG. 4B.

The semiconductor substrate 10 in the source-layer formation region R40 is then etched by the RIE method using the resist 97, the hard mask 95, and the first sidewall dielectric film 100S as a mask. At that time, the top surface S40 of the semiconductor substrate 10 in the source-layer formation region R40 is etched to a position lower than the bottom surface S50b of the pocket layer 50. Accordingly, the source-layer formation region R40 is recessed deeper than the bottom portion of the pocket layer 50 and thus the pocket layer 50 (the N-type impurity layer) located in the source-layer formation region R40 is removed as shown in FIG. 4B. At that time, the side surface of the pocket layer 50 is exposed.

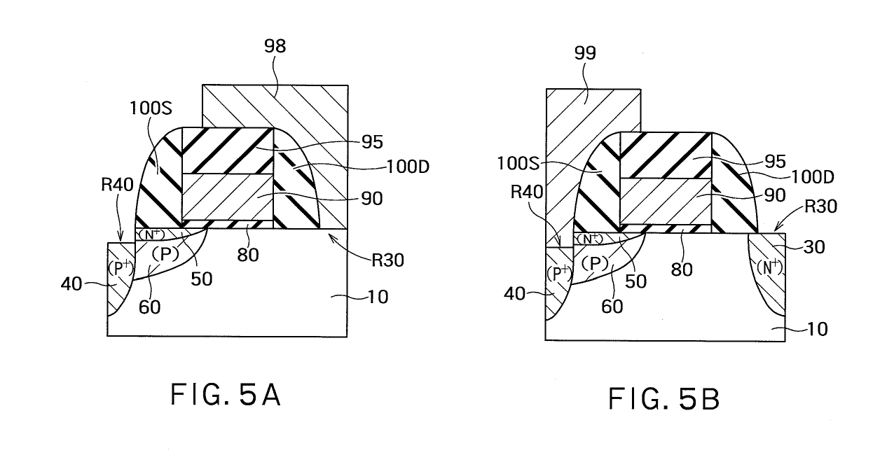

After removal of the resist 97, the drain-layer formation region R30 is covered with a resist 98 using the lithography technique as shown in FIG. 5A. P-type impurity (such as B or BF₂) ions of a high concentration are implanted into the semiconductor substrate 10 in the source-layer formation region R40 using the resist 98, the hard mask 95, and the first sidewall dielectric film 100S as a mask.

After removal of the resist 98, the source-layer formation region R40 is covered with a resist 99 using the lithography technique as shown in FIG. 5B. Next, N-type impurity (such as phosphorus or arsenic) ions of a high concentration are implanted into the semiconductor substrate 10 in the drain-layer formation region R30 using the resist 99, the hard mask 95, and the first sidewall dielectric film 100D as a mask.

After removal of the resist 99, a thermal treatment such as RTA is performed for crystal recovery and impurity activation. The source layer 40 and the drain layer 30 are thereby formed. At that time, a region of the low-concentration layer 70 between the source layer 40 or the extension layer 60 and the drain layer 30 is also defined.

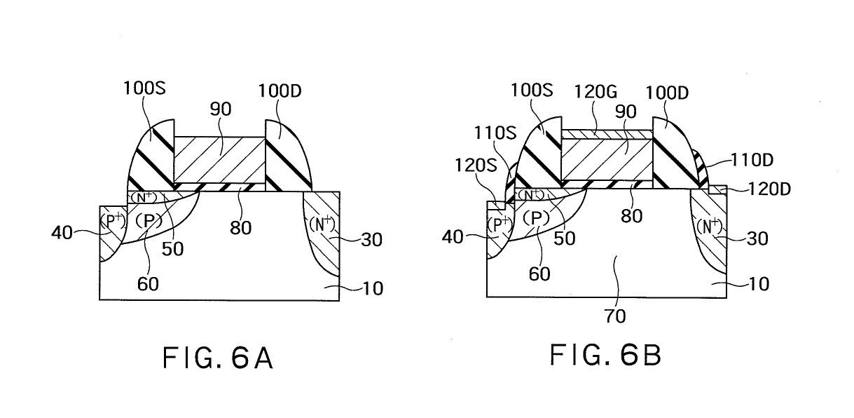

Next, the hard mask 95 is removed using a wet etching method as shown in FIG. 6A.

A material of the second sidewall dielectric films 110S and 110D is then deposited on the semiconductor substrate 10, the first dielectric film dielectric films 100S and 100D, and the gate electrode 90. The material of the second sidewall dielectric films 110S and 110D is an insulating film such as a silicon nitride film. Next, the material is etched back by the RIE method, thereby forming the second sidewall dielectric films 110S and 110D on side surfaces of the first sidewall dielectric films 100S and 100D, respectively, as shown in FIG. 6B. The second sidewall dielectric film 110S is formed on a region of the top surface of the source layer 40 on the side of the gate electrode 90 and covers the side surface of the pocket layer 50. That is, the second sidewall dielectric film 110S is formed also on a part of the top surface of the source layer 40 on the side of the pocket layer 50.

Next, a metal film is deposited on the gate electrode 90, the source layer 40, and the drain layer 30 and is thermally treated, thereby forming the silicide layers 120G, 120S, and 120D as the conductive layers on the gate electrode 90, the source layer 40, and the drain layer 30, respectively, as shown in FIG. 6B. At that time, the first and second sidewall dielectric films 100S, 110S, 100D, and 110D are used as a mask. The silicide layers 120G, 120S, and 120D are low-resistance metal silicide such as NiSi, NiSi₂, or Co₂Si.

The interlayer dielectric film 130, contacts, wires, and the like (not shown) are then formed, whereby the TFET according to the first embodiment is completed.

According to the first embodiment, after formation of the pocket layer 50 and before formation of the source layer 40, the top surface S40 of the source-layer formation region R40 is etched to a position lower than the bottom surface S50b of the pocket layer 50. The pocket layer 50 (the N-type impurity layer) located on the source-layer formation region R40 is removed at that time. Therefore, when the source layer 40 is to be formed, the N-type impurity layer does not remain in the source layer 40 and thus counter-doping is not required. This enables the entire source layer 40 to be brought to a high-concentration P-type impurity layer without the N-type impurity layer left in the source layer 40.

Furthermore, after etching of the source-layer formation region R40, the side surface of the pocket layer 50 is covered with the second sidewall dielectric film 110S. Therefore, a contact of the source silicide layer 120S with the pocket layer 50 during formation of the source silicide layer 120S can be suppressed.

Further, in the first embodiment, when the N-type impurity layer in the source-layer formation region R40 is to be etched, the first sidewall dielectric film 100S covers a portion of the pocket layer 50 near the gate electrode 90. Therefore, the pocket layer 50 is located not only under the gate electrode 90 but also under the first sidewall dielectric film 100S and extends from the channel region toward the source layer 40 up to the second sidewall dielectric film 110S. Accordingly, the interface between the side surface of the pocket layer 50 and the second sidewall dielectric film 110S can be separated from the channel region.

### Second Embodiment

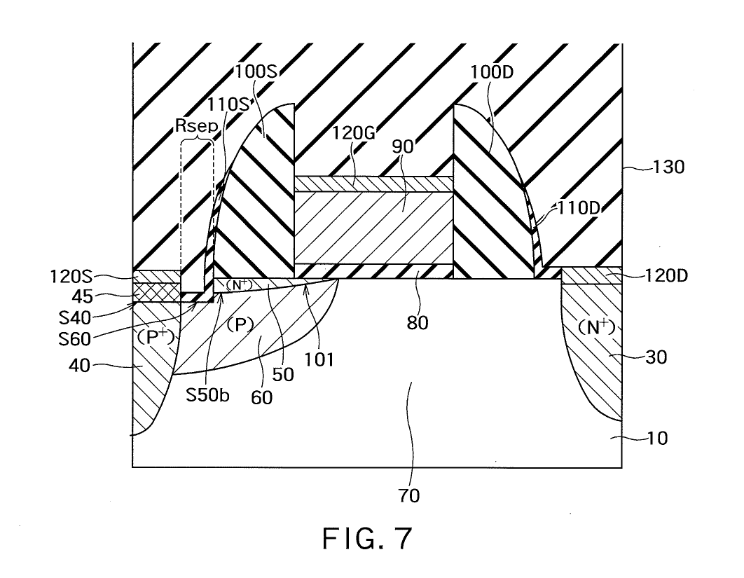

FIG. 7 is a cross-sectional view showing an example of a configuration of a TFET according to a second embodiment. The TFET according to the second embodiment further includes an epitaxial layer 45 provided on the semiconductor substrate 10 of the source layer 40. The epitaxial layer 45 is formed as a high-concentration P-type semiconductor layer and functions as a part of the source layer 40. The source silicide layer 120S is provided on the epitaxial layer 45. When the epitaxial layer 45 is provided between the semiconductor substrate 10 of the source layer 40 and the source silicide layer 120S in this way, a top surface of the source silicide layer 120S can be positioned at an almost equal level to that of a top surface of the drain silicide layer 120D. This relatively facilitates formation of contact plugs and the like (not shown) being in contact with the source silicide layer 120S and the drain silicide layer 120D. However, no problem occurs in the function of the TFET even when the top surface of the source silicide layer 120S is positioned at a level different from that of the top surface of the drain silicide layer 120D.

Furthermore, in the second embodiment, the extension layer 60 is also provided in the semiconductor substrate 10 under the second sidewall dielectric film 110S in the separation region Rsep. In the separation region Rsep, a top surface S60 of the extension layer 60 is positioned at an identical level to that of the top surface S40 of the source layer 40 in the first embodiment and is at a position lower than the bottom surface S50b of the pocket layer 50. This is because the semiconductor substrate 10 in the source-layer formation region is etched to remove the N-type impurities having been introduced into the source-layer formation region at the formation step of the pocket layer 50. Therefore, the second embodiment can achieve effects identical to those of the first embodiment.

Further, the surface S40 of the semiconductor substrate 10 of the source layer 40 is at an almost equal level to that of the top surface S60 of the extension layer 60 (the semiconductor substrate 10) in the separation region Rsep. Therefore, the surface S40 of the semiconductor substrate 10 of the source layer 40 is also at a position lower than the bottom surface S50b of the pocket layer 50 similarly to the top surface S60. Besides, the surface S40 of the semiconductor substrate 10 is an interface between the semiconductor substrate 10 and the epitaxial layer 45. Therefore, it can be seen that the epitaxial layer 45 is formed after the pocket layer 50 in the source-layer formation region is removed by etching.

Because the source layer 40 includes the epitaxial layer 45, a parasitic resistance of the source layer 40 can be reduced.

Other configurations of the second embodiment can be identical to corresponding ones of the first embodiment. Therefore, the second embodiment can also achieve effects of the first embodiment.

A manufacturing method of the TFET according to the second embodiment is explained next.

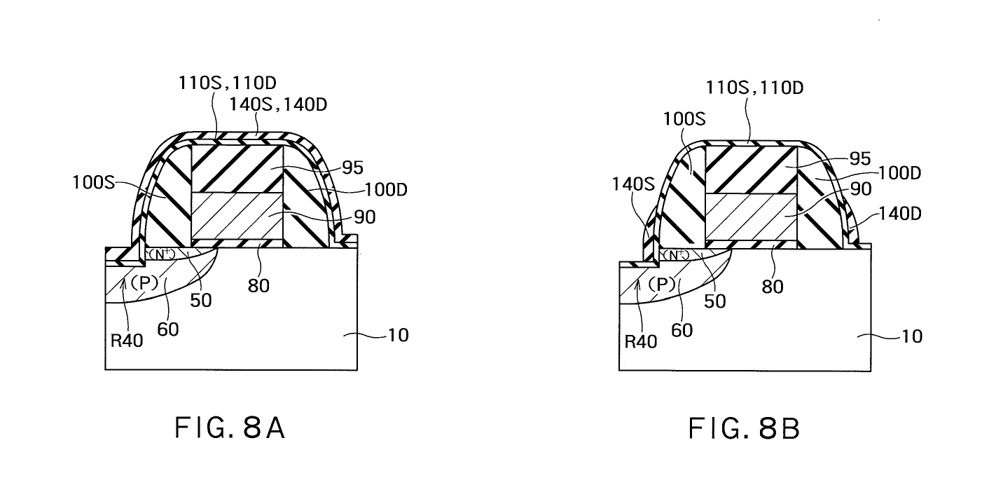

FIGS. 8A to 11B are cross-sectional views showing an example of a manufacturing method of the N-TFET according to the second embodiment. Steps explained with reference to FIGS. 2A to 4B are first performed and the source-layer formation region R40 is etched to a position deeper than the bottom portion of the pocket layer 50. The pocket layer 50 (the N-type impurity layer) located in the source-layer formation region R40 is thereby removed.

Next, a material of the second sidewall dielectric films 110S and 110D is deposited on the semiconductor substrate 10, the first sidewall dielectric films 100S and 100D, and the hard mask 95 as shown in FIG. 8A. The material of the second sidewall dielectric films 110S and 110D is an insulating film such as a TEOS film. A material of third sidewall dielectric films 140S and 140D is further deposited on the material of the second sidewall dielectric films 110S and 110D. The material of the third sidewall dielectric films 140S and 140D is an insulating film such as a silicon nitride film. Because the source-layer formation region R40 has been etched to the position deeper than the bottom portion of the pocket layer 50 at that time, the materials of the second sidewall dielectric films 110S and 110D and the third sidewall dielectric films 140S and 140D cover also the side surface of the pocket layer 50.

Next, the material of the third sidewall dielectric films 140S and 140D is etched back by the RIE method. The third sidewall dielectric films 140S and 140D are thereby formed on the side surfaces of the first sidewall dielectric films 100S and 100D with the material of the second sidewall dielectric films 110S and 110D interposed therebetween, respectively, as shown in FIG. 8B.

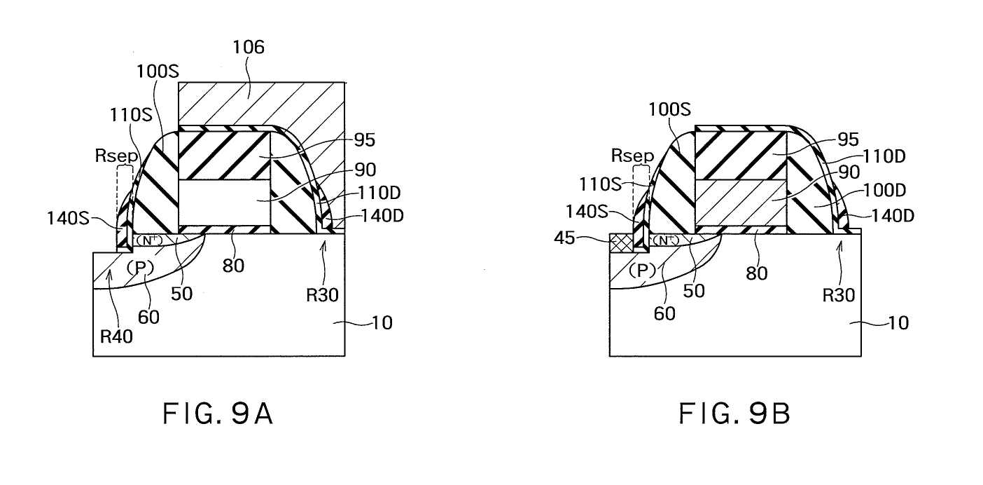

The drain-layer formation region R30 is then covered with a resist 106 using the lithography technique as shown in FIG. 9A. The material of the second sidewall dielectric film 110S in the source-layer formation region R40 is further removed by wet etching using the resist 106 and the third sidewall dielectric film 140S as a mask. The extension layer 60 (the semiconductor substrate 10) is thereby exposed in a part of the source-layer formation region R40. The second and third sidewall dielectric films 110S and 140S are left on the separation region Rsep.

After the resist 106 is removed and a native oxide film of the surface of the exposed extension layer 60 is removed, the epitaxial layer 45 is selectively grown on a portion of the extension layer 60 (the semiconductor substrate 10) exposed in the source-layer formation region R40 using the first to third sidewall dielectric films 100S, 110S, and 140S as a mask. At that time, the second sidewall dielectric film 110S and the third sidewall dielectric film 140S keep a state of covering the top surface of the extension layer 60 and the side surface of the pocket layer 50 in the separation region Rsep. The epitaxial layer 45 is thereby formed at a position separated with the second and third sidewall dielectric films 110S and 140S from the pocket layer 50 by the separation region Rsep as shown in FIG. 9B.

When the second sidewall dielectric film 110S is formed of a silicon dioxide film such as a TEOS film, the second sidewall dielectric film 110S may be removed while the native oxide film of the surface of the extension layer 60 is removed in the previous processing. However, in the second embodiment, the second sidewall dielectric film 110S is covered with the third sidewall dielectric film 140S (a silicon nitride film, for example). Therefore, the second sidewall dielectric film 110S can keep a state of covering the top surface of the extension layer 60 and the side surface of the pocket layer 50 in the separation region Rsep without being removed in the previous processing.

The epitaxial layer 45 can be, for example, silicon, silicon-germanium, or germanium. At this stage, the epitaxial layer 45 can contain the P-type impurities similarly to the source layer 40 or can contain no impurities. Although a film thickness of the epitaxial layer 45 is not particularly limited, it is preferable that a top surface of the epitaxial layer 45 be almost at the same level as that of the surface of the semiconductor substrate 10 in the drain-layer formation region R30.

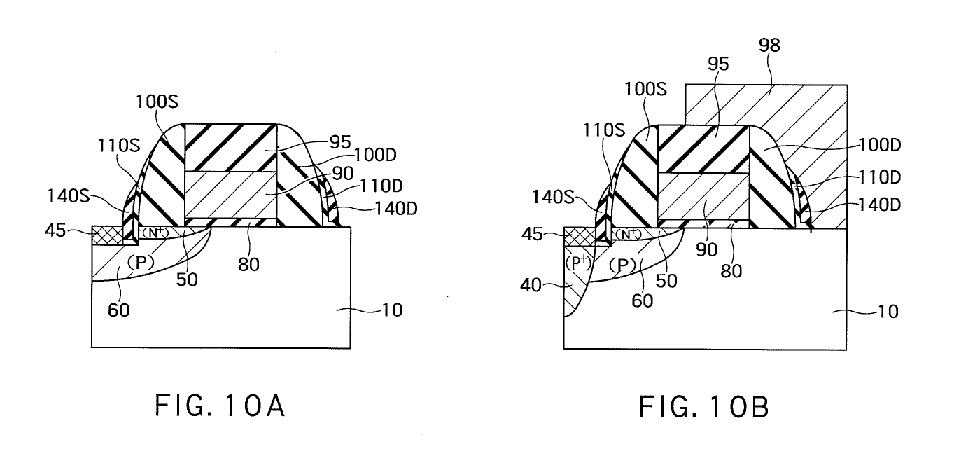

Next, the material of the second sidewall dielectric film 110D is removed by wet etching using the third sidewall dielectric film 140D as a mask as shown in FIG. 10A. The second sidewall dielectric films 110S and 110D are thereby formed between the side surfaces of the first sidewall dielectric films 100S and 100D and the third sidewall dielectric films 140S and 140D, respectively, as shown in FIG. 10A.

Next, the drain-layer formation region R30 is covered with the resist 98 using the lithography technique as shown in FIG. 10B. P-type impurity (such as B or BF₂) ions of a high concentration are implanted into the epitaxially layer 45 and the semiconductor substrate 10 in the source-layer formation region R40 using the resist 98, the hard mask 95, and the first to third sidewall dielectric films 100S, 110S, and 140S as a mask.

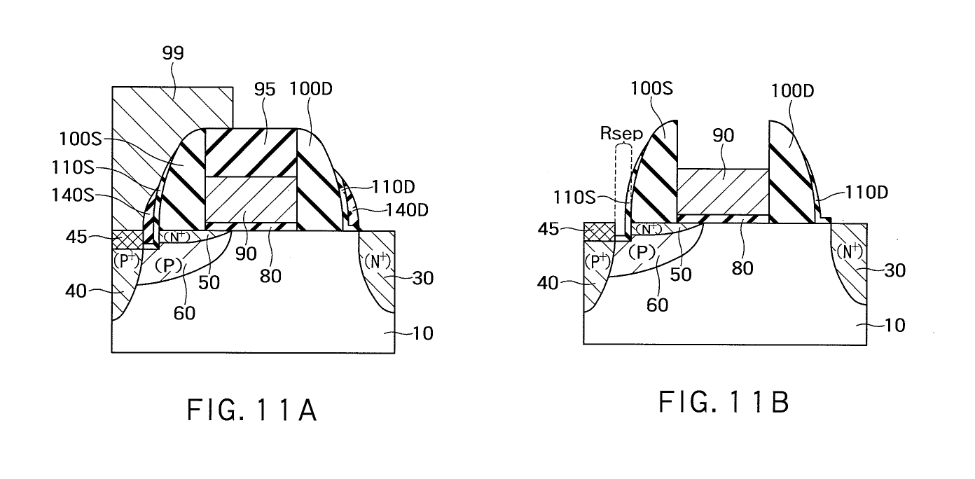

After the resist 98 is removed, the source-layer formation region R40 is covered with the resist 99 using the lithography technique as shown in FIG. 11A. Next, N-type impurity (such as phosphorus or arsenic) ions of a high concentration are implanted into the semiconductor substrate 10 in the drain-layer formation region R30 using the resist 99, the hard mask 95, and the first to third sidewall dielectric films 100D, 110D, and 140D as a mask.

After the resist 99 is removed, a thermal treatment such as RTA is performed for crystal recovery and impurity activation. The source layer 40 and the drain layer 30 are thereby formed. At that time, a region of the low-concentration layer 70 is also defined between the source layer 40 or the extension layer 60 and the drain layer 30. The epitaxial layer 45 also contains the P-type impurities of a high concentration and functions similarly to the source layer 40. Therefore, the epitaxial layer 45 can be considered as a part of the source layer 40.

Next, the hard mask 95 is removed by the wet etching method as shown in FIG. 11B. At that time, when the third sidewall dielectric films 140S and 140D are formed of the same insulating film as the hard mask 95 (the silicon nitride film, for example), the third sidewall dielectric films 140S and 140D are also removed. The second sidewall dielectric film 110S keeps the state of covering the top surface of the extension layer 60 and the side surface of the pocket layer 50 in the separation region Rsep.

Subsequently, a metal film is deposited on the gate electrode 90, the epitaxial layer 45, and the drain layer 30 and is thermally treated, thereby forming the silicide layers 120G, 120S, and 120D as the conductive layers on the gate electrode 90, the epitaxial layer 45, and the drain layer 30, respectively, as shown in FIG. 7. The silicide layers 120G, 120S, and 120D are low-resistance metal silicide such as NiSi, NiSi₂, or Co₂Si and the like.

The interlayer dielectric film 130, contacts, wires, and the like (not shown) are then formed, whereby the TFET according to the second embodiment is completed.

The drain-layer formation region R30 is covered with the resist 106 at a step shown in FIG. 9A. However, an epitaxial layer can be formed also in the drain-layer formation region R30 without forming the resist 106. In this case, a lithography step of forming the resist 106 can be omitted. Meanwhile, the top surface of the source silicide layer 120S and the top surface of the drain silicide layer 120D are different in the level from each other, which do not cause any problem in the function of the TFET.

According to the second embodiment, the source silicide layer 120S is formed higher than the surface of the semiconductor substrate 10 of the source layer 40 by the thickness of the epitaxially layer 45. Therefore, the top surface of the source silicide layer 120S can be positioned at an almost equal level to that of the top surface of the drain silicide layer 120D. This relatively facilitates formation of contact plugs and the like (not shown) being in contact with the source silicide layer 120S and the drain silicide layer 120D.

In the second embodiment, the top surface S40 of the source-layer formation region R40 is etched to a position lower than the bottom surface S50b of the pocket layer 50 to remove the pocket layer 50 (the N-type impurity layer) located on the source-layer formation region R40 similarly to the first embodiment. While the second sidewall dielectric film 110S has a different shape, the side surface of the pocket layer 50 is covered with the second sidewall dielectric film 110S. Therefore, the second embodiment can achieve effects identical to those of the first embodiment.

### Third Embodiment

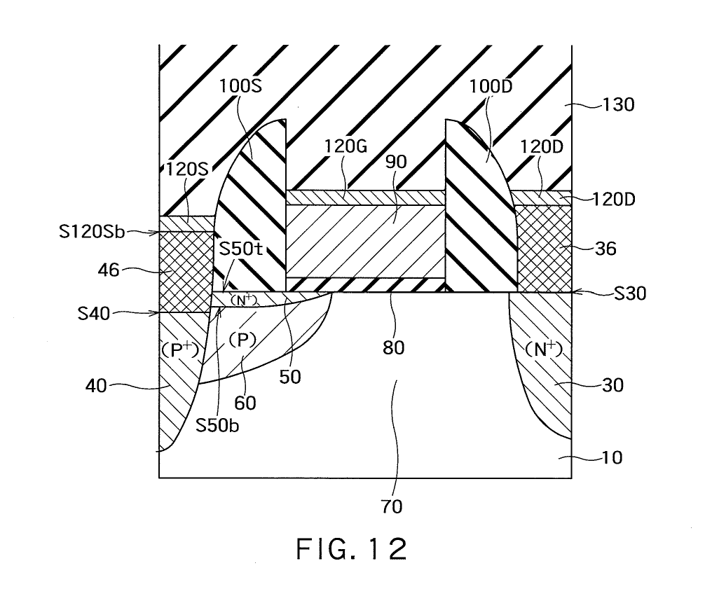

FIG. 12 is a cross-sectional view showing an example of a configuration of a TFET according to a third embodiment. The TFET according to the third embodiment further includes a source epitaxial layer 46 provided on the semiconductor substrate 10 in the region of the source layer 40 and a drain epitaxial layer 36 provided on the semiconductor substrate 10 in the region of the drain layer 30.

The source epitaxial layer 46 is formed as a high-concentration P-type semiconductor layer and functions as a part of the source layer 40. The source silicide layer 120S is provided on the source epitaxial layer 46. The drain epitaxial layer 36 is formed as a high-concentration N-type semiconductor layer and functions as a part of the drain layer 30. The drain silicide layer 120D is provided on the drain epitaxial layer 36.

In the third embodiment, the separation region Rsep is not provided and a side surface of the source epitaxial layer 46 is in contact with the side surface of the first sidewall dielectric film 100S and the side surface of the pocket layer 50. When the source epitaxial layer 46 is made of a different semiconductor material from the semiconductor substrate 10, a contact portion between the source epitaxial layer 46 and the side surface of the pocket layer 50 is a heterojunction portion.

The level of an interface S40 between the semiconductor substrate 10 of the source layer 40 and the source epitaxial layer 46 is lower than the level of the bottom surface S50b of the pocket layer 50. This is because the top surface S40 of the semiconductor substrate 10 is etched to a position lower than the bottom surface S50b of the pocket layer 50 to remove a portion of the semiconductor substrate 10 in the source-layer formation region to which the N-type impurities have been introduced at the formation step of the pocket layer 50. This etching step removes the N-type impurities in the formation region of the source layer 40, thereby enabling to suppress an N-type impurity layer from remaining in the source layer 40. Accordingly, a leak current between the source layer 40 and the pocket layer 50 can be suppressed.

The level of a bottom surface S120Sb of the source silicide layer 120S is higher than the level of a top surface S50t of the pocket layer 50. Therefore, the source silicide layer 120S is not in contact with the pocket layer 50 and is separated from the pocket layer 50. This suppresses a flow of a leak current from the source silicide layer 120S to the pocket layer 50.

Meanwhile, because the drain epitaxial layer 36 is also provided on the drain layer 30, the drain silicide layer 120D is provided at a position higher than the surface of the semiconductor substrate 10 similarly to the source silicide layer 120S.

In FIG. 12, an interface S30 between the semiconductor substrate 10 of the drain layer 30 and the drain epitaxial layer 36 is almost equal to the level of the top surface S50t of the pocket layer 50 and is located at a position higher than the interface S40 between the semiconductor substrate 10 and the source epitaxial layer 46. Associated therewith, the drain silicide layer 120D is formed at a position higher than the source silicide layer 120S. Also in such a mode, no particular problem occurs in the characteristics of the TFET. However, the interface S30 can be recessed to a level almost equal to the interface S40. In this case, the drain silicide layer 120D is formed at an almost equal level to the source silicide layer 120S. This relatively facilitates formation of contact plugs and the like (not shown) being in contact with the source silicide layer 120S and the drain silicide layer 120D.

Furthermore, the TFET according to the third embodiment includes the source epitaxial layer 46 and the drain epitaxial layer 36 on the source layer 40 and the drain layer 30, respectively. This can reduce parasitic resistances of the source layer 40 and the drain layer 30.

Other configurations of the third embodiment can be identical to corresponding ones of the first embodiment.

A manufacturing method of the TFET according to the third embodiment is explained next.

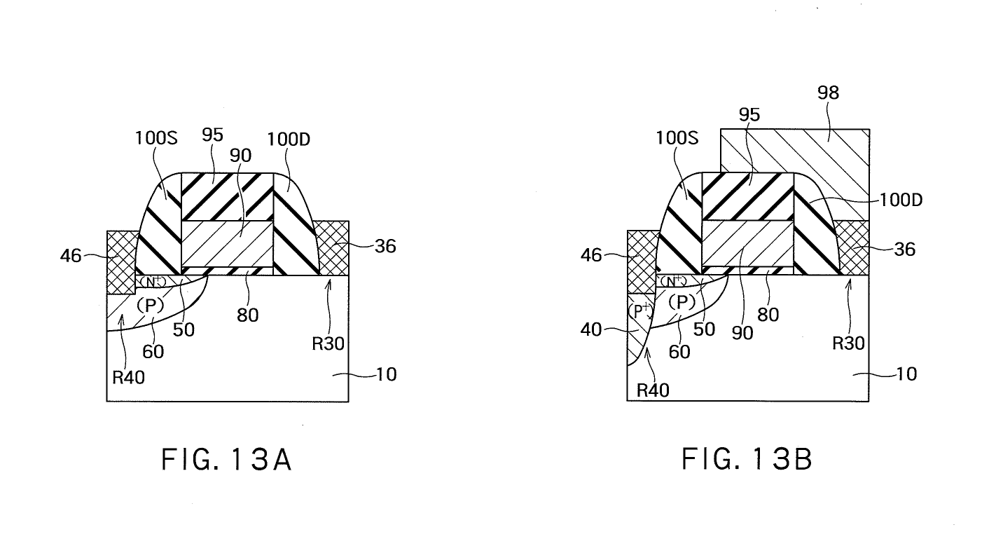

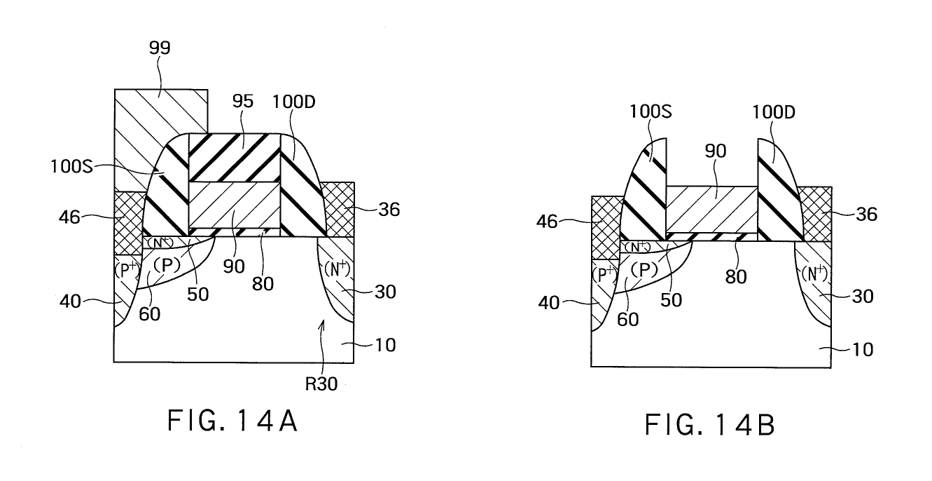

FIGS. 13A to 14B are cross-sectional views showing an example of a manufacturing method of the N-TFET according to the third embodiment. The steps explained with reference to FIGS. 2A to 4B are first performed and the source-layer formation region R40 is etched (recessed) to a position deeper than the bottom portion of the pocket layer 50. The pocket layer 50 (the N-type impurity layer) located in the source-layer formation region R40 is thereby removed.

Next, after a native oxide film of an exposed surface of the semiconductor substrate 10 is removed, the source epitaxial layer 46 is selectively grown on an exposed portion of the semiconductor substrate 10 in the source-layer formation region R40 using the first sidewall dielectric films 100S and 100D as a mask as shown in FIG. 13A. With this growth, the drain epitaxial layer 36 is selectively grown on an exposed portion of the semiconductor substrate 10 in the drain-layer formation region R30.

The epitaxial layers 46 and 36 can be, for example, silicon, silicon-germanium, or germanium. At that time, the epitaxial layers 46 and 36 preferably contain no impurities. Film thicknesses of the epitaxial layers 46 and 36 are formed thicker than the depth of a recess in the source-layer formation region R40 (at least the thickness of the pocket layer 50) to prevent the source silicide layer 120S from being in contact with the pocket layer 50.

Next, the drain-layer formation region R30 is covered with the resist 98 using the lithography technique as shown in FIG. 13B. P-type impurity (such as B or BF₂) ions of a high concentration are then implanted into the source epitaxial layer 46 and the semiconductor substrate 10 in the source-layer formation region R40 using the resist 98, the hard mask 95, and the first sidewall dielectric film 100S as a mask.

After the resist 98 is removed, the source-layer formation region R40 is covered with the resist 99 using the lithography technique as shown in FIG. 14A. Next, N-type impurity (such as phosphorus or arsenic) ions of a high concentration are implanted into the drain epitaxial layer 36 and the semiconductor substrate 10 in the drain-layer formation region R30 using the resist 99, the hard mask 95, and the first sidewall dielectric film 100D as a mask.

After the resist 99 is removed, a thermal treatment such as RTA is performed for crystal recovery and impurity activation. The source layer 40 and the drain layer 30 are thereby formed. At that time, the low-concentration layer 70 is also defined between the source layer 40 or the extension layer 60 and the drain layer 30. The source epitaxial layer 46 contains the P-type impurities of a high concentration and functions similarly to the source layer 40. Therefore, the source epitaxial layer 46 can be considered as a part of the source layer 40. The drain epitaxial layer 36 contains the N-type impurities of a high concentration and functions similarly to the drain layer 30. Therefore, the drain epitaxial layer 36 can be considered as a part of the drain layer 30.

Next, the hard mask 95 is removed by a wet etching method as shown in FIG. 14B.

A metal film is then deposited on the gate electrode 90 and the epitaxial layers 46 and 36 and is thermally treated, thereby forming the silicide layers 120G, 120S, and 120D as the conductive layers on the gate electrode 90, the source epitaxial layer 46, and the drain epitaxial layer 36, respectively, as shown in FIG. 12. The silicide layers 120G, 120S, and 120D are low-resistance metal silicide such as NiSi, NiSi₂, or Co₂Si.

Thereafter, the interlayer dielectric film 130, contacts, wires, and the like (not shown) are formed, whereby the TFET according to the third embodiment is completed.

In the third embodiment, the top surface S40 of the source-layer formation region R40 is etched to a position lower than the bottom surface S50b of the pocket layer 50 to remove the pocket layer 50 (the N-type impurity layer) located on the source-layer formation region R40 as in the first embodiment. Therefore, the third embodiment can suppress a leak current between the source layer 40 and the pocket layer 50 similarly to the first embodiment.

The bottom surface S120Sb of the source silicide layer 120S is located at a position higher than the top surface S50t of the pocket layer 50. This suppresses a direct contact between the source silicide layer 120S and the pocket layer 50. Therefore, the third embodiment can suppress a leak current between the source silicide layer 120S and the pocket layer 50 similarly to the first embodiment.

Furthermore, the manufacturing method of the TFET according to the third embodiment is easily applicable to manufacturing steps of a MOSFET (hereinafter, also “raised MOSFET”) having so-called a raised source and a raised drain. In some cases of the raised MOSFET, portions of a semiconductor substrate in a source region and a drain region are recessed and then epitaxial layers are formed on the source region and the drain region, respectively. For example, it is assumed that portions of a silicon substrate in a source region and a drain region are recessed and then silicon-germanium layers are epitaxially grown on the source region and the drain region as epitaxial layers, respectively. In this case, a stress is applied to a channel region due to a difference in the lattice constant between silicon-germanium and silicon and a mobility of charges in the MOSFET can be enhanced.

Such a recessing step of the portions of the semiconductor substrate in the source region and the drain region in the raised MOSFET can be adapted to the etching step of the pocket layer 50 (the N-type impurity layer) in the source-layer formation region R40 in the third embodiment. Furthermore, a formation step of the epitaxial layers in the source region and the drain region in the raised MOSFET can be adapted to the formation step of the source epitaxial layer 46 and the drain epitaxial layer 36 in the third embodiment. As described above, the TFET according to the third embodiment can be formed at the same manufacturing steps as those of the raised MOSFET. As a result, the manufacturing cost can be reduced.

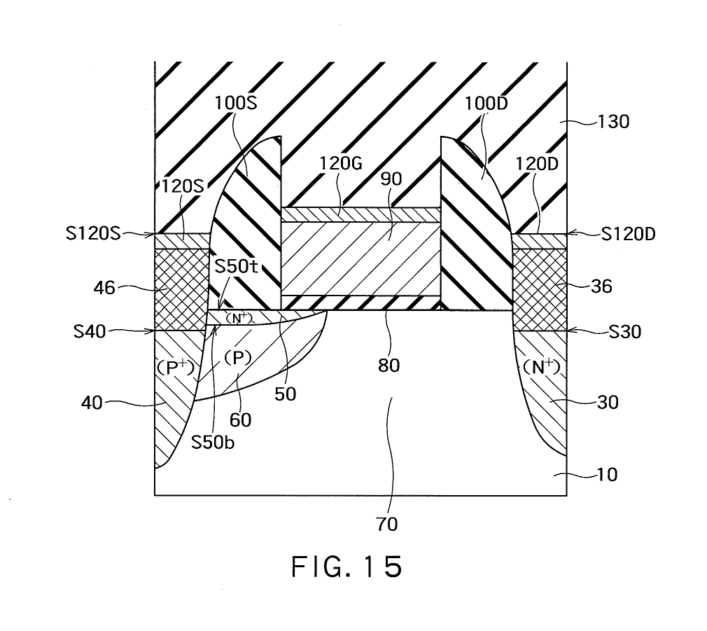

In the first to third embodiments, the drain-layer formation region R30 is not etched at the etching step of the pocket layer 50 (the N-type impurity layer) located in the source-layer formation region R40. However, the drain-layer formation region R30 can be also etched at this etching step similarly to the source-layer formation region R40. While the semiconductor substrate 10 in the drain-layer formation region R30 is thereby etched, no problem occurs in the characteristics of the TFET. On the other hand, the lithography step for covering the drain-layer formation region R30 is not required and thus the manufacturing steps of the TFET can be shortened. Furthermore, the levels of the top surfaces of the drain layer 30 (or the drain silicide layer 120D) and the source layer 40 (or the source silicide layer 120S) can be formed almost equal to each other. For example, FIG. 15 shows an embodiment in which the levels of the top surfaces of the drain layer 30 (or the drain silicide layer 120D) and the source layer 40 (or the source silicide layer 120S) are formed almost equal to each other. In this embodiment, a level of the interface S30 between the semiconductor substrate 10 and the drain epitaxial layer 36 is substantially equal to the level of the interface S40 between the semiconductor substrate 10 and the source epitaxial layer 46. Furthermore, a level of the top surface S120D of the drain silicide layer 120D is substantially equal to a level of the top surface S120S of the source silicide layer 120S. Therefore, a source contact and a drain contact can be formed easily.

In the first to third embodiments, embodiments of the N-TFET have been explained. However, the first to third embodiments are also applicable to a P-TFET. In this case, it suffices to replace the P-type semiconductor with an N-type semiconductor, replace the N-type semiconductor with a P-type semiconductor, replace the P-type impurities with N-type impurities, and to replace the N-type impurities with P-type impurities in constituent elements of the first to third embodiments. While a case where as the conductive layer the silicide layer is formed on the source layer and the like has been explained, a case where formation of the silicide layer is omitted in the first to third embodiments is quite effective in sufficiently separating a source contact formed on the source layer as the conductive layer from the pocket layer and consequently suppressing a leak current from the source contact to the pocket layer.

Furthermore, the top surface S40 of the source layer 40 is located at a position lower than the bottom surface S50b of the pocket layer 50 in the first to third embodiments. However, the top surface S40 of the source layer 40 can be positioned at a level (a depth) equal to the bottom surface S50b of the pocket layer 50. This is because, also in this case, the source-layer formation region R40 is recessed to a level (a depth) equal to the bottom portion of the pocket layer 50 and thus the N-type impurities having been introduced into the formation region of the source layer 40 at the formation step of the pocket layer 50 can be removed. Therefore, even when the top surface S40 of the source layer 40 is located at a level equal to the bottom surface S50b of the pocket layer 50 in the first to third embodiments, effects of the first to third embodiments can be achieved.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
a gate dielectric film on the semiconductor substrate;
a gate electrode on the gate dielectric film;
a first diffusion layer of a first conductivity type in a part of a surface of the semiconductor substrate under the gate dielectric film;
a second diffusion layer of a second conductivity type in the semiconductor substrate under the first diffusion layer, the second conductivity type being a conductivity type different from the first conductivity type, the second diffusion layer being in contact with a bottom portion of the first diffusion layer and forming a PN junction with the bottom portion of the first diffusion layer;
a drain layer of the first conductivity type in the semiconductor substrate on one side of the gate electrode;
a source layer of the second conductivity type in the semiconductor substrate on other side of the gate electrode to be adjacent to the second diffusion layer;
a first sidewall dielectric film on a side surface of the gate electrode and on a top surface of the first diffusion layer; and
a conductive layer on the source layer at a position separated from the first sidewall dielectric film, wherein
a top surface of the semiconductor substrate in a separation region between the first sidewall dielectric film and the conductive layer is at a position equal to or lower than a bottom surface of the first diffusion layer.

2. The device of claim 1, further comprising a second sidewall dielectric film on the semiconductor substrate in the separation region, the second sidewall dielectric film covering a side surface of the first diffusion layer.

3. The device of claim 2, wherein the conductive layer includes a source silicide layer and the second sidewall dielectric film is interposed between the first diffusion layer and the source silicide layer.

4. The device of claim 2, wherein the first diffusion layer is below the gate electrode and the first sidewall dielectric film and extends from a channel region below the gate electrode to the second sidewall dielectric film.

5. The device of claim 1, wherein the source layer is located in the semiconductor substrate in the separation region.

6. The device of claim 1, wherein the second diffusion layer is located in the semiconductor substrate in the separation region.

7. The device of claim 1, further comprising:
an epitaxial layer on the semiconductor substrate in a region of the source layer, wherein
the conductive layer includes a source silicide layer,
the source silicide layer is located on the epitaxial layer, and
a top surface of the semiconductor substrate in the source layer is at a substantially equal level to the top surface of the semiconductor substrate in the separation region.

8. The device of claim 7, further comprising:
a drain silicide layer on the drain layer, wherein
a top surface of the source silicide layer is at a substantially equal level to a top surface of the drain silicide layer.

9. A semiconductor device comprising:
a semiconductor substrate;
a gate dielectric film on the semiconductor substrate;
a gate electrode on the gate dielectric film;
a first diffusion layer of a first conductivity type in a part of a surface of the semiconductor substrate under the gate dielectric film;
a second diffusion layer of a second conductivity type in the semiconductor substrate under the first diffusion layer, the second conductivity type being a conductivity type different from the first conductivity type, the second diffusion layer being in contact with a bottom portion of the first diffusion layer and forming a PN junction with the bottom portion of the first diffusion layer;
a drain layer of the first conductivity type in the semiconductor substrate on one side of the gate electrode;
a source layer of the second conductivity type in the semiconductor substrate on other side of the gate electrode to be adjacent to the second diffusion layer;
a first sidewall dielectric film on a side surface of the gate electrode and on a top surface of the first diffusion layer;
a source epitaxial layer on the semiconductor substrate in a region of the source layer; and
a conductive layer on the source epitaxial layer to be separated from the first diffusion layer, wherein
a level of an interface between the semiconductor substrate and the source epitaxial layer is equal to or lower than a level of a bottom surface of the first diffusion layer.

10. The device of claim 9, wherein a level of a bottom surface of the conductive layer is higher than a level of a top surface of the first diffusion layer.

11. The device of claim 9, wherein a side surface of the source epitaxial layer is in contact with side surfaces of the first sidewall dielectric film and the first diffusion layer.

12. The device of claim 9, further comprising:
a drain epitaxial layer on the semiconductor substrate in a region of the drain layer; and
a conductive layer on the drain epitaxial layer.

13. The device of claim 12, wherein the conductive layer on the source epitaxial layer includes a source silicide layer and the conductive layer on the drain epitaxial layer includes a drain silicide layer,
a level of an interface between the semiconductor substrate and the drain epitaxial layer is substantially equal to the level of the interface between the semiconductor substrate and the source epitaxial layer, and
a level of a top surface of the drain silicide layer is substantially equal to a level of a top surface of the source silicide layer.

14. A manufacturing method of a semiconductor device, the method comprising:
introducing first conductivity type impurities for forming a first diffusion layer while introducing second conductivity type impurities for forming a second diffusion layer from a source-layer formation region to a diffusion-layer formation region adjacent to the source-layer formation region in a semiconductor substrate so that the second diffusion layer is in contact with a bottom portion of the first diffusion layer and forms a PN junction with the bottom portion of the first diffusion layer, the second conductivity type being a conductivity type different from the first conductivity type;
forming a first sidewall dielectric film covering a side surface of a gate electrode above the semiconductor substrate to be located on a part of the first diffusion layer;
etching a portion of a surface of the semiconductor substrate in the source-layer formation region using the first sidewall dielectric film as a mask to lower a top surface of the semiconductor substrate in the source-layer formation region to a position equal to or lower than a bottom surface of the first diffusion layer; and
introducing second conductivity type impurities for forming a source layer into the source-layer formation region using the first sidewall dielectric film as a mask.

15. The method of claim 14, further comprising forming a source silicide layer above the source layer.

16. The method of claim 15, further comprising forming a second sidewall dielectric film covering side surfaces of the first sidewall dielectric film and the first diffusion layer after etching in the source-layer formation region, wherein
the source silicide layer is formed on the source layer using the second sidewall dielectric film as a mask.

17. The method of claim 15, further comprising:
after etching in the source-layer formation region,
forming a second sidewall dielectric film covering side surfaces of the first sidewall dielectric film and the first diffusion layer; and
forming an epitaxial layer on the semiconductor substrate in the source-layer formation region using the second sidewall dielectric film as a mask, wherein
the source silicide layer is formed on the epitaxial layer.

18. The method of claim 15, further comprising:
after etching in the source-layer formation region,
forming an epitaxial layer on the semiconductor substrate in the source-layer formation region, wherein
the source silicide layer is formed on the epitaxial layer.

19. The method of claim 18, wherein
the epitaxial layer is formed up to a position higher than the first diffusion layer, and
a bottom surface of the source silicide layer is formed at a position higher than a top surface of the first diffusion layer.

20. The method of claim 18, wherein
an epitaxial layer is formed also on the semiconductor substrate in a drain-layer formation region, when the epitaxial layer is formed on the semiconductor substrate in the source-layer formation region, and
a drain silicide layer is formed on the epitaxial layer in the drain-layer formation region, when the source silicide layer is formed on the epitaxial layer in the source-layer formation region.
